(19) United States
(12) Patent Application Publication
(10) Pub. No.: US 2008/0002372 A1
(43) Pub. Date: Jan. 3, 2008

(54) Easy and secure destruction of credit card

(75) Inventors: Scott Edwards Kelso, Durham, NC (US); John Carl Mese, Cary, NC (US); Nathan J. Peterson, Raleigh, NC (US); Rod D. Waltermann, Rougemont, NC (US); Arnold S. Weksler, Raleigh, NC (US)

Correspondence Address: DUKE W. YEE;YEE & ASSOCIATES, P.C., P.O. BOX 802333, DALLAS, TX, 75380, US

(73) Assignee: Lenovo (Singapore) Pte. Ltd., Singapore (SG)

(21) Appl. No.: 11/476,438

(22) Filed: Jun. 28, 2006

(51) Int. Cl. H05K 1/14

(52) U.S. Cl. 361/737

(57) ABSTRACT

A card formed with a cavity located within the card. The cavity is used to hold one or more liquid chemicals. Additional hollow regions abut the visual and magnetic versions of the sensitive data and are normally separated from the chemicals. When the card is sharply folded, the chemicals are released from the cavity and flow in the hollow regions abutting the stored data. The chemicals render the data unreadable, such as by obscuring the visual display with an opaque film. Additionally, in at least some embodiments, the magnetic strip on the credit card is implemented in such a way that there are two separate portions, with the encoded data divided in such a way that both portions are required in order to be decoded.

### BACKGROUND OF THE INVENTION

1. Field of the Invention

The present invention relates to credit cards and related types of cards and to a means to effectively destroy the information they contain.

2. Description of the Related Art

Financial cards, such as credit cards and debit cards typically contain account information such as the account number, owner's name, and expiration date. This information is generally found in at least two different formats. In the first format, the text is embossed into the plastic for use visually and with older paper systems. The second format uses a magnetic strip containing the information in a computer-readable form; the magnetic strip may also include a personal identification number. When the card is no longer useful, such as after the card is expired or is cancelled, it is desirable to destroy the information recorded on the card for security reasons. The current recommendation is to cut the card into a number of small pieces so that it is difficult or impossible to reconstruct the data from the pieces. However, this method of destruction is not foolproof and the concern over theft necessitates an alternate, and more reliable, manner of information destruction. Thus, it would be desirable to have a method to destroy the recorded information without the need to physically cut up the card.

### BRIEF SUMMARY OF THE INVENTION

A card is formed with a cavity located within the card. The cavity is used to hold one or more liquid chemicals. Additional hollow regions abut the visual and magnetic versions of the sensitive data and are normally separated from the chemicals. When the card is sharply folded, the chemicals are released from the cavity and flow in the hollow regions abutting the stored data. The chemicals render the data unreadable, such as by obscuring the visual display with an opaque film and interfering with the magnetically stored information. Additionally, in at least some embodiments, the magnetic strip on the card is implemented in such a way that there are two separate portions, with the encoded data divided in such a way that both portions are required in order to be decoded.

### BRIEF DESCRIPTION OF THE SEVERAL VIEWS OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1A is a view of the front of a card according to an exemplary embodiment;

FIG. 1B is a view of the back of a card according to an exemplary embodiment;

FIG. 2A is a cross-section of the layers used to create a card according to an exemplary embodiment;

FIG. 2B is an exploded view of the layers of FIG. 2A, according to an exemplary embodiment;

FIG. 3 is a cross-section of the layers used to create a card according to an alternate exemplary embodiment;

FIG. 4 shows the back of a card made according to FIG. 3, after the liquid chemicals have been released in patterned channels in accordance with an exemplary embodiment;

FIG. 5 is a cross-section of the layers used to create a card according to a further alternate exemplary embodiment;

FIG. 6 is a cross-section of the layers used to create a card containing an integrated circuit according to an exemplary embodiment; and

FIG. 7 is a cross-section of the layers used to create a card according to an alternate exemplary embodiment in which liquid is introduce into the card from an exterior source when destruction of the data is desired.

### DETAILED DESCRIPTION OF THE INVENTION

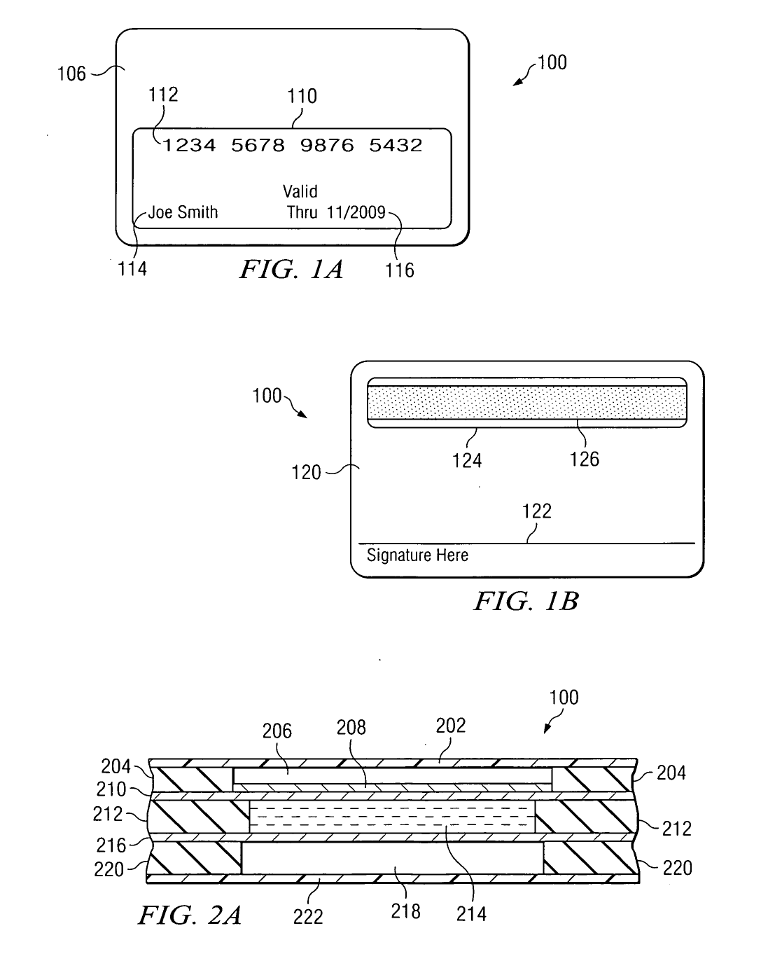

With reference now to the figures and with particular reference to FIGS. 1A and 1B, an embodiment of the invention will now be discussed. FIG. 1A is a view of the front of card 100, according to an exemplary embodiment. The main portion 106 of the front of card 100 is generally opaque and may contain, for example, a logo, an identification of the provider of the card, and/or graphic art. The visual account information lies in a shallow recessed area and is covered by a clear window 110. Exemplary window 110 displays account number 112, name of account owner 114, and expiration date 116. Window 110 can also contain additional information, such as a holographic validity indicator, a fingerprint, or a photographic identification.

FIG. 1B shows the back of card 100 according to an exemplary embodiment of the invention. As on the front, the main portion 120 of the back of card 100 is generally opaque and contains signature line 122. Clear window 124 covers a shallow recess containing magnetic strip 126.

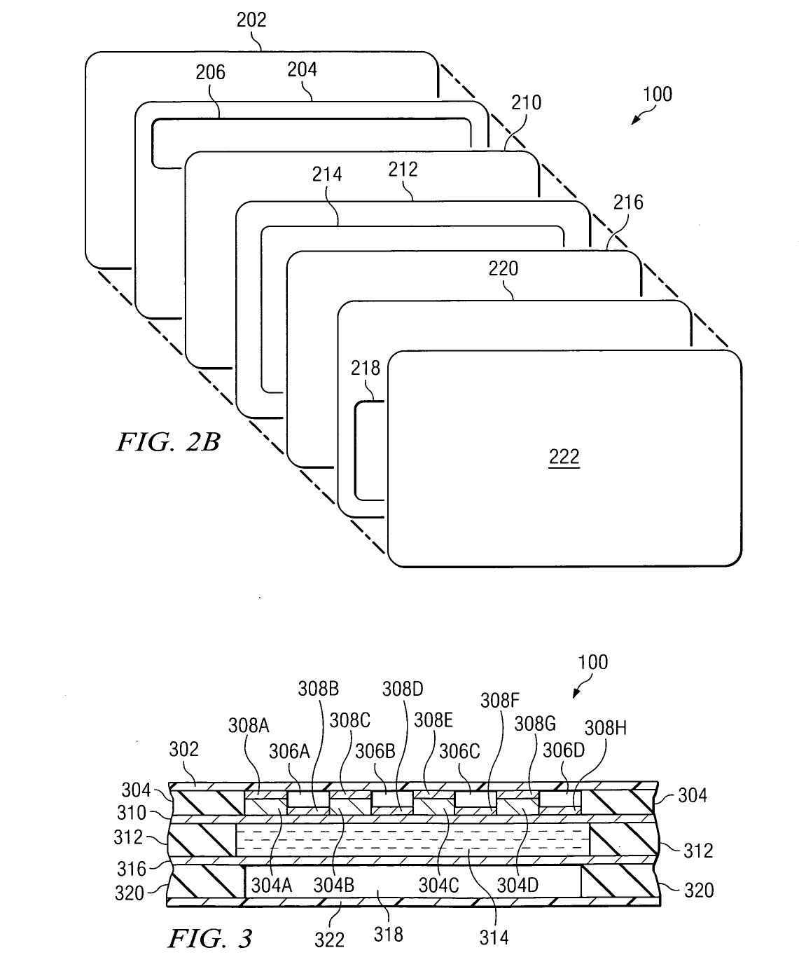

FIG. 2A shows an edge-wise cross-section through exemplary card 100, while FIG. 2B shows the same layers in an exploded view. These exemplary figures contain multiple, thin layers of plastic, such as polyvinylchloride, which are laminated or otherwise fused together, forming a flattened body for card 100 (i.e., the card is significantly thinner than it is long or wide). The card can alternatively be formed of any new materials utilized in the industry, either presently in use or replacing plastic in its current form. It should be understood that the thicknesses of the layers depicted have been chosen for clarity of the drawing and do not represent the actual relative thicknesses of the layers.

Top layer 202 and bottom layer 222 are clear, solid layers that completely cover the upper and lower surfaces of card 100, respectively. Layer 204 and layer 220 are each seen in cross-section as two distinct sections on the outer edges of their respective layer. As better seen in FIG. 2B, these layers are patterned with respective, generally rectangular openings that form empty cavities 206 and 218 in card 100. Magnetic strip 208 is affixed to a wall of cavity 206 by means known in the art and corresponds to magnetic strip 126 in FIG. 1B.

Layer 212 in the center of the cross-section also contains opening 214, which is filled with the liquid chemicals in the finished card. Cavities 206 and 218 are separated from cavity 214 by solid layers 210 and 216. Layers 210 and 216 each form breakable barriers between the liquid chemical(s) and the information. As breakable barriers, layers 210 and 216 prevent the migration of the liquid chemicals toward the stored information unless a specific force is applied to card 100.

Layers 210 and 216 are chosen to be of a stiffness and a thickness that will withstand the normal, minor bending that a card can receive in use, but that will break apart or fail in a manner that allows a liquid to pass through the layers when a specific force is applied to card 100. In a preferred embodiment, the force is applied by bending the card beyond a pre-determined angle. In an exemplary embodiment, bending the card to a ninety degree angle is sufficient to cause the breakable barriers to fail. In alternate embodiments, the degree of bending necessary to destroy layers 210 and 216 can be designed to fall in the range of sixty to one hundred twenty degrees. This breakage allows the liquid in cavity 214 to move into cavities 206 and 218, respectively through breaks or failures in layers 210 and 216. In these examples, outer layers 202 and 222, although shown as the same thickness as layers 210 and 216, are chosen to have a thickness and makeup that will bend without breaking or cracking under the same stress that is necessary to break layers 210 and 216. In these examples, outer layers 202 and 222 are selected such that these layers fail with a greater amount of bending.

FIG. 3 shows an alternate embodiment of the cross-section of exemplary card 100 of FIGS. 1A and 1B. This embodiment is identical to the embodiment shown in FIG. 2A, except for the region containing the magnetic strip.

In this illustrative embodiment, layer 304 contains steps 304A, 304B, 304C, and 304D. Segments 308A-H of magnetic tape lie on different levels, with segments 308A, 308C, 308E, and 308G of the tape being on raised steps 304A, 304B, 304C, and 304D, respectively, while segments 308B, 308D, 308F, and 308H have cavities 306A, 306B, 306C, and 306D, respectively, immediately above them.

The magnetic tape can still be read from a ninety degree angle, even when segmented. When this card is sharply bent, the released chemicals will only contact the surface of those segments of the magnetic tape that have a cavity above them. However, the identifying information is spread across the magnetic strip, so the destruction of a portion of the magnetic strip will keep identity thieves from recovering the necessary information. When this embodiment is utilized, there is an option to deliberately shape the channel into which the liquid(s) are released on bending.

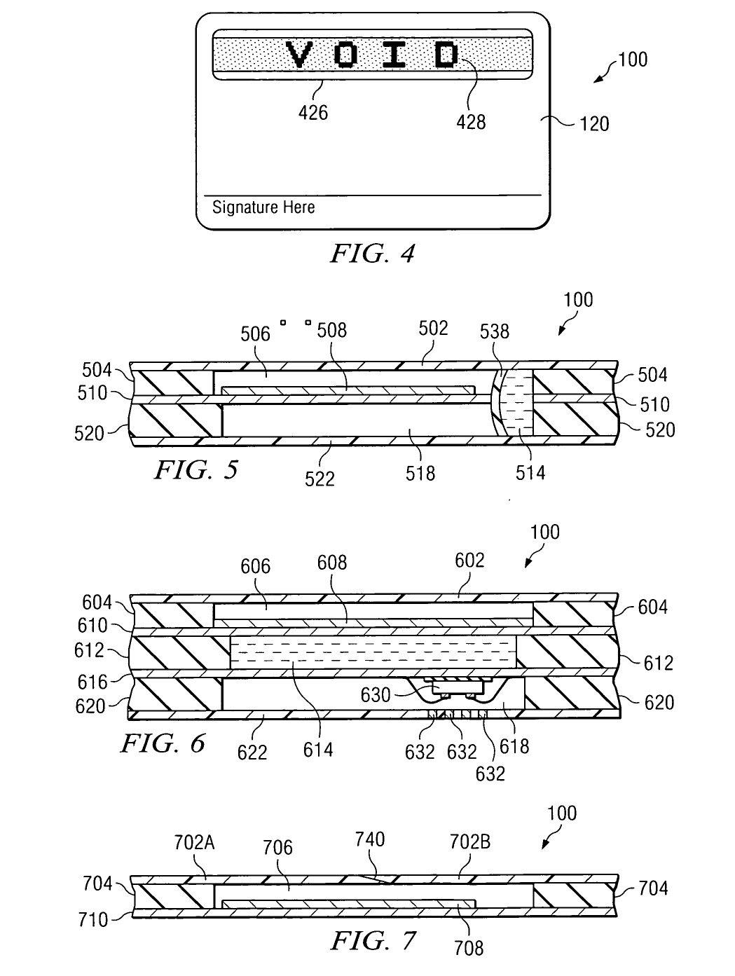

FIG. 4 demonstrates an embodiment of card 100 in which the channels 428 overlying the magnetic strip 426 are shaped so that when the channel is filled, the word “VOID” is spelled out in a color contrasting to the magnetic strip 426.

FIG. 5 demonstrates an alternate embodiment of card 100. In this embodiment, a single inner layer 510 provides support for magnetic tape 508 on one side and for a visual display on the opposite side. Along with layers 502, 504, 520, and 522, layer 510 defines cavities 506, 518. Cavity 514 containing the destructive liquid is not positioned between cavities 506 and 518. Instead, cavity 514 is defined by a wall or membrane 538 on one side and by portions of layers 502, 504, 510, 520, and 522 on the other sides. Bending card 100 in this embodiment causes wall or membrane 538 to break or rupture, allowing its content to enter both cavity 506 and cavity 518.

FIG. 6 demonstrates a further embodiment of card 100 in which the card contains an integrated circuit. In this embodiment, layers 602 through 616 are identical to the corresponding layers in FIG. 2A. However, integrated circuit 630 is affixed to layer 616 as is known in the art and contacts 632 are embedded in layer 622. This figure shows integrated circuit 630 lying within a cavity 618 corresponding to the cavity in which text information is displayed in FIG. 2A, but the text information and integrated circuit 630 can also be laterally displaced from each other and be contained in separate cavities. Likewise, liquid 614 can be chosen to destroy all of the different forms of stored information (e.g., magnetic strip, text, and integrated circuit) or alternatively two or more liquids can be contained within separate cavities in card 100 and each be tailored to optimally destroy a specific type of storage device.

FIG. 7 shows yet another possible embodiment of card 100. A single cavity 706 is formed by transparent layer 702 and layers 704 and 710. All information is affixed to layer 710, such as magnetic strip 708. In this embodiment, however, no liquid is stored within card 100. Transparent layer 702 is formed of two sections 702A and 702B. Layer 702 is formed in such a manner that sections 702A and 702B form a tight seal at their intersection 740 while card 100 is in normal use. However, when card 100 is bent beyond a predetermined angle, sections 702A and 702B separate at intersection 740, allowing a liquid to be introduced into cavity 706. In this embodiment, the user bends card 100, then places card 100 under a running stream of water, which destroys the information stored in cavity 706.

Various options can be utilized for the chemical combination used to destroy information on the card. Examples of some possible solutions include:
Water, or a water-based combination, to dissolve text, which is written in a water soluble ink or dye and to cause the integrated circuit to separate from its board;
An ink or dye to form an opaque barrier over the text;
A liquid bearing magnetic properties to render the magnetic strip unreadable;
A liquid epoxy and a hardener, stored in separate compartments, to block the view of the text when mixed and to interfere with reading of magnetic strip while preventing the card from being taken apart;
A mild acid or alkaline solution to etch the surfaces of the text and the magnetic tape. This latter solution is less desirable because of possible adverse effects if the liquid leaks from the card, or
A semiconductor etchant to etch the integrated circuit;
Combinations of any of the above liquids.

Although the descriptions of exemplary cards have been directed to credit cards, it will be understood that embodiments of the inventive card can also be utilized as debit cards or as cards containing any other type of sensitive information, such as membership cards, gift cards, check cards, driver's licenses, and identification cards.

Additionally, the card has been described in term of layers of plastic material fused together, but some or all of the layers can also be molded or shaped by other means to create a card as described in the claims below.

In summary, the disclosed invention provides an addition to a card carrying sensitive information, such as financial information. The card contains a cavity that is filled with a liquid, the liquid chosen to destroy at least some of the sensitive information on contact. The liquid is normally separated from the media carrying the sensitive information by a breakable barrier. Upon bending of the card to a designed degree, the barrier is broken and the liquid released to perform its destruction of information.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A card containing data, the card comprising:
a flattened body formed substantially of plastic;
a first hollow cavity formed within the flattened body, wherein one wall of the first hollow cavity is a first breakable barrier that is designed to fail in response to a force applied to the card;
a data storage device affixed to a portion of the flattened body, wherein at least a portion of the data storage device is located within the flattened body such that when a liquid is admitted into the first hollow cavity, the liquid destroys any information stored in the storage device.

2. The card of claim 1, further comprising:
a second hollow cavity, separated from the first hollow cavity by the first breakable barrier, the second hollow cavity containing the liquid, wherein the liquid enters the first hollow cavity when the breakable barrier fails in response to the force applied to the breakable barrier.

3. The card of claim 2, further comprising a third hollow cavity that is separated from the second hollow cavity by a second breakable barrier.

4. The card of claim 1, wherein the card further comprises a visual display that contains a name, an account number, and an expiration date.

5. The card of claim 4, wherein the visual display further contains at least one item chosen from the group consisting of a holographic validation sticker, a fingerprint, and a photographic identification.

6. The card of claim 1, wherein the data storage device is one of a magnetic strip, a memory circuit, or a chip with data registers.

7. The card of claim 1, wherein the data storage device is encoded with a name, an account number, an expiration date, and a personal identification number.

8. The card of claim 1, wherein the liquid chemical consists of a liquid chosen from the group of water, a water-based solution, a dye, a liquid bearing magnetic properties, epoxy, a mild acid, a mild alkaline, and a semiconductor etchant.

9. The card of claim 1, wherein the card is chosen from the group consisting of a debit card, a credit card, a membership card, a gift card, a check card, a driver's license, and an identification card.

10. The card of claim 1, wherein the force required for the first breakable barrier to fail is bending the card to an angle of at least sixty degrees.

11. The card of claim 1, wherein the first breakable barrier is designed to break in a manner that provides an opening through which a user introduces water into the first hollow cavity.

12. A method of destroying a card carrying information, the method comprising:
bending the card beyond a pre-determined angle, wherein a liquid chemical stored in a first cavity in the card is released into a hollow chamber located adjacent a data storage device affixed to the card, such that the liquid destroys the information in the data storage device.

13. The method of claim 12, wherein the card is chosen from the group consisting of a credit card, a debit card, a membership card, a gift card, a check card, a drivers license, and an identification card.

14. The method of claim 12, wherein the sensitive information is human-readable text.

15. The method of claim 12, wherein the sensitive information is encoded on a magnetic strip.

16. The method of claim 12, wherein the liquid chemical consists of a liquid chosen from the group of water, a water-based solution, a dye, a ferrous dye, an epoxy and hardener, a mild acid, and a mild alkaline.

17. A card containing data, the card comprising:
a flattened body formed substantially of plastic;
a first hollow cavity formed within the flattened body;
a magnetic strip affixed to the flattened body, wherein at least a portion of the magnetic strip abuts the first hollow cavity; and
a second hollow cavity, separated from the first hollow cavity by a breakable barrier, the second hollow cavity containing a liquid chemical that will destroy information stored on the magnetic strip.

18. The card of claim 17, wherein the liquid chemical consists of a liquid chosen from the group of water, a water-based solution, a dye, a liquid bearing magnetic properties, epoxy, a mild acid, a mild alkaline, and a semiconductor etchant.

19. The card of claim 17, further comprising visual information that includes a user name, an account number, and an expiration date.

20. The card of claim 17, wherein the breakable barrier is designed to break when the card is bent a predetermined number of degrees between 60 and 120 degrees.
